(19) United States
(12) Patent Application Publication
(10) Pub. No.: US 2024/0413583 A1
(43) Pub. Date: Dec. 12, 2024

(54) SECURING DEVICE HAVING AN INDICATOR ELEMENT AND ORIENTATION ELEMENTS

(71) Applicant: Lisa Dräxlmaier GmbH, Vilsbiburg (DE)

(72) Inventors: Stefan WIMMER, Hohenthann (DE); Sebastian WILHELM, Schmelz (DE); Franziska NEUMAYER, Geisenhausen (DE)

(73) Assignee: Lisa Dräxlmaier GmbH, Vilsbiburg (DE)

(21) Appl. No.: 18/735,659

(22) Filed: Jun. 6, 2024

(30) Foreign Application Priority Data
Jun. 6, 2023 (DE) 102023114793.5

(51) Int. Cl. H01R 13/641; H01R 13/629

(52) U.S. Cl. CPC H01R 13/641; H01R 13/62933

(57) ABSTRACT

A securing device for securing the locking of a locking element including a locking element that moves from a first locking position into a second locking position. The locking element produces locking in the second locking position. The securing device further includes an indicator element for indicating an item of information. In the first locking position, the indicator element is visible and is not concealed. The indicator element has one or more orientation elements for marking a position of the indicator element. The indicator element can be detected via the one or more orientation elements. In the first locking position, the one or more orientation elements are made at least partially unidentifiable, such that the indicator element cannot be detected. In the second locking position of the locking element, the one or more orientation elements are made identifiable, such that the indicator element can be detected.

### CROSS-REFERENCE TO RELATED APPLICATIONS

This application claims priority to and the benefit of DE 10 2023 114 793.5 filed on Jun. 6, 2023. The disclosure of the above-referenced application is incorporated herein by reference.

### FIELD

The present disclosure relates to a securing device to secure the locking of a locking element.

### BACKGROUND

The statements in this section merely provide background information related to the present disclosure and may not constitute prior art.

CPA (connector position assurance) systems are intended to inhibit a connector housing latched to a mating connector housing from being inadvertently detached from the mating connector housing, as can happen for example due to vibrations, temperature-related expansion or shrinkage, pulling on a cable accommodated in the connector housing, or other mechanical effects. For this, the CPA system is responsible for locking the connector to its mating connector, as the last element to be operated. In order to provide secure locking here, it is desired for the final state of the locking to be detected by virtue of a scannable element and for this element to be readable when the CPA system is finally closed.

### SUMMARY

This section provides a general summary of the disclosure and is not a comprehensive disclosure of its full scope or all of its features.

The present disclosure relates to a securing device having an indicator element and orientation elements. The securing device serves to secure the locking of a locking element or for connector position assurance (CPA) and can be used to secure the locking of a connector housing to a mating connector housing. In particular, the present disclosure relates to a CPA system having a DMC (data matrix code), in the case of which the orientation elements are controlled.

The present disclosure provides a suitable device to reliably discern if locking is present or not, in particular for connectors for which CPA locking is desired.

The connector may have a high degree of automation in terms of production and fabrication makes the use of a scannable element desired as an assurance function. The present disclosure presented here relates to a securing device having an indicator element which includes one or more orientation elements and can be used as a scannable element, in order to thus provide reliable assurance of the connector production process and make it possible to scan the plug system in the assembled state. The present disclosure may be applied to various plug systems and can be easily adapted from one plug system to another plug system.

The main principle of the present disclosure is the control of the orientation elements or position markers of a DMC. The DMC is applied to the CPA system with a peripheral black frame. Actuating the CPA system makes it slide underneath the clip. There is a cutout in the clip. This cutout is designed such that the orientation elements can be discerned clearly again. The DMC is not concealed. It is only represented such that the orientation elements are not discernible in position 1, or the first locking position. In a second variant or example, an additional edge is slid around the orientation elements on the DMC, in order to make them harder to discern.

A main feature of the present disclosure is the control of the detectability by manipulating the orientation elements. The DMC is always represented completely, but the orientation elements cannot be detected owing to an additional black frame, which is around the DMC.

The basic principle lies in controlling the orientation elements of a DMC, as described in more detail below in relation to FIGS. 2A and 2B and also 3A and 3B. The orientation elements of a DMC may be clearly discernible. If they are manipulated, like for the DMC in FIG. 2A or 3A, the DMC cannot be detected. This basic principle can be transferred to the operation of a CPA system, as described in more detail below in relation to FIGS. 4A to 4C. The DMC is applied to the CPA system with a peripheral black frame. Actuating the CPA system results in the CPA system sliding underneath the clip. There is a cutout in the clip. This cutout is designed such that the orientation elements can be discerned clearly again. In a second variant or example (see FIGS. 3A and 3B), an additional edge is slid around the orientation elements on the DMC, in order to make them harder to discern.

According to a first aspect, the present disclosure provides a securing device for securing the locking of a locking element, wherein the securing device includes the following: a locking element, which can be moved from a first locking position into a second locking position, wherein the locking element produces locking in the second locking position; and an indicator element for indicating an item of information, wherein, in the first locking position, the indicator element is always visible and is not concealed, wherein the indicator element has one or more orientation elements for marking a position of the indicator element, wherein the indicator element can be detected via the one or more orientation elements; wherein, in the first locking position of the locking element, the one or more orientation elements are made at least partially unidentifiable, with the result that the indicator element cannot be detected; and wherein, in the second locking position of the locking element, the one or more orientation elements are made identifiable, with the result that the indicator element can be detected.

Such a securing device affords the technical advantage that it is possible to securely and reliably discern locking. The indicator element can be detected via a scannable element, with the result that it is possible to reliably automatically discern the position of the locking element. This also makes it possible to automatically detect the state of connectors for which CPA locking is desired. The securing device thus meets the standards for CPA locking.

According to one example of the securing device, in the first locking position, the one or more orientation elements are made unidentifiable without concealing the one or more orientation elements.

This affords the technical advantage that the orientation elements are still visible and are not concealed. A mechanism for concealing the orientation elements may be omitted.

According to one example of the securing device, the indicator element has an identifying feature with a data area for the purpose of detecting the identifying feature, wherein the one or more orientation elements are placed on an edge of the data area; and wherein, when the orientation elements are made at least partially unidentifiable, the identifying feature can no longer be detected. The identifying feature may be, for example, a code, for example a one-, two- or three-dimensional code.

This affords the technical advantage that the orientation elements can easily be made unidentifiable when they are on the edge of the identifying feature, and that the identifying feature can be efficiently made unidentifiable via the orientation elements.

According to one example of the securing device, the identifying feature has a quiet area which runs around the periphery of the data area and the orientation elements, wherein, in the first locking position of the locking element, the quiet area is at least partially concealed and the identifying feature is no longer identifiable as a result.

This affords the technical advantage that the orientation elements can easily be made unidentifiable by concealing the quiet area. It may already be sufficient, for example, to conceal or to modify only a part of the quiet area, in order to make the orientation elements unidentifiable.

According to one example of the securing device, the indicator element has an edge, which runs around the periphery of the identifying feature and makes the one or more orientation elements unidentifiable; wherein, in the second locking position, the edge is concealed by a frame, which makes the one or more orientation elements identifiable.

This affords the technical advantage that the peripheral edge, which lies for example on the quiet area of the identifying feature but not on the orientation elements themselves, already makes the orientation elements unidentifiable. The frame can then be laid on the edge in order to produce the quiet area again and make the orientation elements discernible again.

According to one example of the securing device, the edge has the same color as or a similar color to the orientation elements; and the frame has a color which contrasts with the color of the edge.

This affords the technical advantage that the edge makes the orientation elements unidentifiable and the frame makes the orientation elements identifiable again.

According to one example of the securing device, the identifying feature includes a code, for example a data matrix code, DMC.

The data matrix code is one of the best known 2D codes and can be used for permanent and robust direct labelling. The DMC is variable in size and thus permits a multiplicity of symbol elements.

According to one example of the securing device, the indicator element is placed on the locking element and a movement of the locking element into the second locking position makes the indicator element detectable.

This affords the technical advantage that the second locking position, which is linked to a locking action, can be indicated and detected efficiently.

According to one example of the securing device, the indicator element is discernible, for example can be read via a reader or is visually discernible, when the one or more orientation elements are not made at least partially unidentifiable.

This affords the technical advantage that the state of the locking element can be determined securely and reliably via a reader, for example a scanner, or can be visually discerned easily. This makes it possible to efficiently assure automated mounting of plug systems and it is possible to make random visual inspections.

According to one example of the securing device, the securing device is designed to perform connector position assurance (CPA) to secure the locking of a connector housing to a mating connector housing.

This affords the technical advantage that the state of the CPA system can be reliably detected by virtue of a scannable element, which is readable only when the CPA system is finally closed.

According to one example of the securing device, the securing device also includes: a clamping element for clamping the connector housing into the mating connector housing, wherein the clamping element can be moved from an open clamping-element position, in which the connector housing can be inserted into the mating connector housing, into a closed clamping-element position, in which the connector housing is fastened to the mating connector housing with electrical contact; wherein the locking element is placed on the clamping element and designed to lock or to unlock the clamping element.

This affords the technical advantage that the indicator element can reliably indicate an item of information, for example an item of information about the locking or non-locking of the clamping element, for example a clip, so that the state of the clamping element can be efficiently detected via a scannable element or visually.

According to one example of the securing device, in the closed clamping-element position, the locking element can be moved from the first locking position into the second locking position and is designed, in the second locking position, to lock the clamping element in the closed clamping-element position and, in the first locking position, to unlock the clamping element for a movement into the open clamping-element position.

This affords the technical advantage that a secure connection of the connector housing to the mating connector housing via the clamping element is provided. The securing device thus meets the standards for CPA locking.

According to one example of the securing device, the clamping element has a cutout; wherein the indicator element is placed on the clamping element; and wherein, when the locking element is being moved into the second locking position, the indicator element is moved underneath the cutout in the clamping element, and therefore makes the one or more orientation elements identifiable, with the result that the indicator element can be detected.

This affords the technical advantage that the clamping element can serve as a frame, which can be slid over the edge around the two-dimensional code, in order to thus make the orientation elements identifiable again.

According to a second aspect, the present disclosure provides a plug connection having a connector housing and a mating connector housing, which are connected to one another and secured by a securing device according to the first aspect.

According to a third aspect, the present disclosure provides a securing system including a securing device according to the first aspect and a reader, wherein the reader is designed to detect the indicator element when the locking element is in the second locking position, in order to discern locking.

According to one example of the securing system, the reader is designed to detect the indicator element only when the locking element is in the second locking position and to detect correct locking only in this position.

### DRAWINGS

In order that the disclosure may be well understood, there will now be described various forms thereof, given by way of example, reference being made to the accompanying drawings, in which:

FIG. 1 shows a schematic illustration of the states of a securing device according to the present disclosure;

FIG. 2A shows an illustration of an indicator element according to the present disclosure with orientation elements made unidentifiable, according to a first example;

FIG. 2B shows an illustration of the indicator element from FIG. 2A according to the first example, in which the orientation elements are made identifiable;

FIG. 3A shows an illustration of an indicator element according to the present disclosure applied to the CPA system, in which the orientation elements are made unidentifiable, according to a second example;

FIG. 3B shows an illustration of the indicator element from FIG. 3A according to the second example, in which the orientation elements are made identifiable;

FIG. 4A shows a perspective view of a closed securing device including a locking element, an indicator element according to the first example of the present disclosure, and a clamping element in an open clamping-clip position;

FIG. 4B shows a perspective view of an open securing device including a locking element, an indicator element according to the first example of the present disclosure, and a clamping element in a closed clamping-clip position; and

FIG. 4C shows a perspective view of an open securing device including a locking element, an indicator element according to the second example of the present disclosure, and a clamping element in an open clamping-clip position.

The figures are merely schematic illustrations and serve only to explain the present disclosure. Elements that are the same or have the same effect are provided with the same reference signs throughout.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

In the detailed description that follows, reference is made to the accompanying drawings, which form a part thereof and which show, as an illustration, examples in which the present disclosure can be carried out. It goes without saying that other examples can also be used and structural or logical changes can be made without departing from the concept of the present disclosure. The detailed description that follows should therefore not be understood in a restrictive sense. It also goes without saying that the features of the various examples described herein can be combined with one another unless specifically stated otherwise.

The aspects and examples are described with reference to the drawings, wherein reference signs that are the same generally relate to the same elements. Numerous specific details are set out for the purposes of explanation in the description that follows in order to provide an in-depth understanding of one or more aspects of the present disclosure. However, it may be obvious to a person skilled in the art that one or more aspects or examples can be implemented with a lesser degree of the specific details. In other cases, known structures and elements are illustrated in a schematic form in order to make it easier to describe one or more aspects or examples. It goes without saying that other examples can be used and structural or logical changes can be made without departing from the concept of the present disclosure.

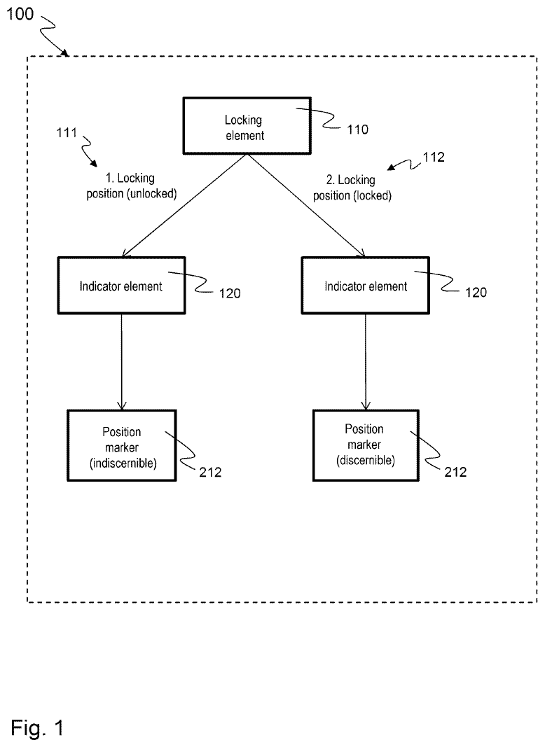

FIG. 1 shows a schematic illustration of the states of a securing device 100 according to the present disclosure.

The securing device 100 serves to secure the locking of a locking element 110. The securing device 100 includes a locking element 110 and an indicator element 120.

The locking element 110 can be moved from a first locking position 111 into a second locking position 112 and produces locking in the second locking position 112.

The indicator element 120 serves to indicate an item of information, for example an item of information about the locking by the locking element 110, or else any other information.

The indicator element 120 has one or more orientation elements 212 for marking a position of the indicator element 120. The indicator element 120 can be detected via the one or more orientation elements 212.

In the first locking position 111 of the locking element 110, the one or more orientation elements 212 are made at least partially unidentifiable, with the result that the indicator element 120 cannot be detected.

In the second locking position 112 of the locking element 110, the one or more orientation elements 212 are made identifiable, with the result that the indicator element 120 can be detected.

In particular, in the first locking position 111, the one or more orientation elements 212 are made unidentifiable without concealing the one or more orientation elements 212.

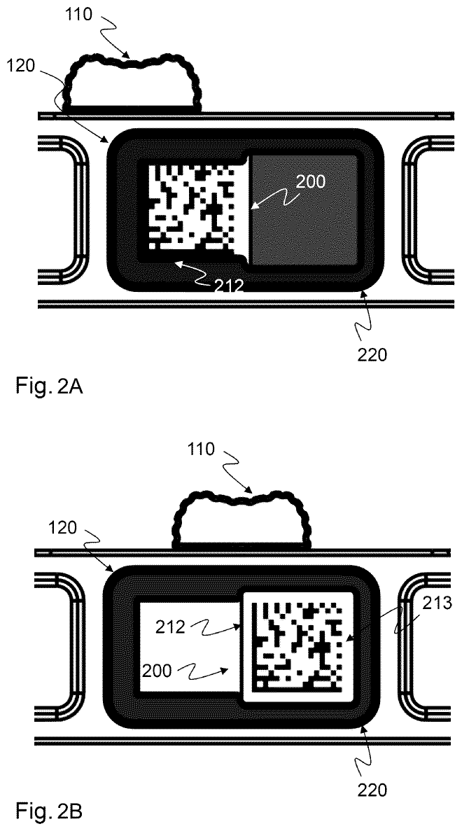

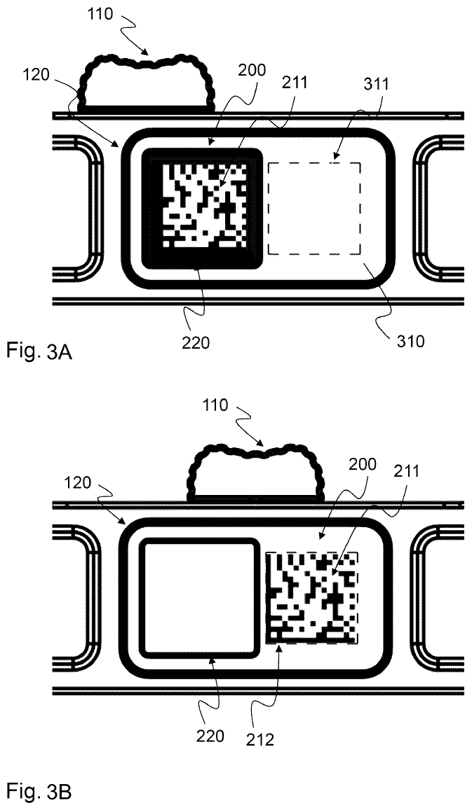

Examples of the indicator element 120 with a description of how the orientation elements 212 can be made unidentifiable or identifiable without concealing them are described in more detail in relation to FIGS. 2A, 2B, 3A and 3B.

FIGS. 2A and 2B show a 2D illustration of an indicator element 120 according to the present disclosure with orientation elements 212 made unidentifiable (FIG. 2A) or identifiable (FIG. 2B).

The indicator element 120 has an identifying feature 200, for example a one-, two- or multi-dimensional code, for example a DMC. The identifying feature includes a data area 211 for the purpose of detecting the identifying feature 200. The one or more orientation elements 212 are placed on an edge of the data area 211, as illustrated in FIG. 2A. When the orientation elements 212 are made at least partially unidentifiable, the identifying feature 200 can no longer be detected.

The identifying feature 200 has a quiet area 213 which runs around the periphery of the data area 211 and the orientation elements 212, as illustrated in FIG. 2B. In the first locking position 111 of the locking element 110, the quiet area 213 is at least partially concealed and the identifying feature 200 is no longer identifiable as a result.

The indicator element 120 has an edge 220, which runs around the periphery of the identifying feature 200 and makes the one or more orientation elements 212 unidentifiable, as illustrated in FIG. 2A. In the second locking position 112, the edge 220 is concealed by a light-colored frame, which makes the one or more orientation elements 212 identifiable again.

The edge 220 has the same color as or a similar color to the orientation elements 212, which in FIG. 2A is a black color, although it may also be another dark color. The frame has a color which contrasts with the color of the edge 220, which in FIG. 2B is a white color, although it may also be another light color.

The identifying feature 200 may be a code, for example a data matrix code, DMC.

Such a data matrix code includes or consists, for example, of the following main components:

1) two pairs of solid continuous edges and interrupted edges as boundary lines (finder pattern or orientation element or position marker). The solid boundary lines serve for delimitation. They are used to align and equalize the data matrix code, so that any reading angle is possible.

2) a peripheral quiet zone. This empty zone surrounds the data matrix code. It does not contain any information or patterns. The width of the quiet zone is at least one gap or line (in one example four times the width, or height, of a module) and is desired for delimitation from other optical image elements of the surrounding area.

3) the corner situated opposite the closed edges. This corner makes it possible to quickly discern the code schemata. In the case of the identifying feature 200 being a code scheme ECC, with an even number of lines and gaps, the element in the upper right-hand corner is white. In the case of the other standardized code schemata, with an odd number of lines and gaps, the element in the upper right-hand corner is black.

4) the alignment pattern. This combination in pairs of continuous and interrupted lines in both directions, horizontally and vertically, makes it easier to evaluate the image. They subdivide large data fields into equally sized parts in the case of codes with an edge length of at least 32 modules.

5) the data area. This data area contains the actual binary information in coded form. Depending on the size of the matrix, the number of possible items of information is also defined in this way.

FIGS. 3A and 3B show a 2D illustration of an indicator element 120 according to the present disclosure which is applied to the CPA system and has orientation elements 212 made unidentifiable (FIG. 3A) or identifiable (FIG. 3B).

The indicator element 120 has an identifying feature 200, for example a one-, two- or multi-dimensional code, for example a DMC. The identifying feature includes a data area 211 for the purpose of detecting the identifying feature 200, as set out above in relation to FIGS. 2A and 2B. The one or more orientation elements 212 are placed on an edge of the data area 211, as illustrated in FIG. 3A. As already described above in relation to FIGS. 2A and 2B, the identifying feature 200 can no longer be detected when the orientation elements 212 are made at least partially unidentifiable.

The identifying feature 200 has a quiet area 213 which runs around the periphery of the data area 211 and the orientation elements 212, as set out above in relation to FIG. 2B. In the first locking position 111 of the locking element 110, the quiet area 213 is at least partially concealed and the identifying feature 200 is no longer identifiable as a result, as illustrated in FIG. 3A.

The indicator element 120 has an edge 220, which runs around the periphery of the identifying feature 200 and makes the one or more orientation elements 212 unidentifiable, as illustrated in FIG. 2A. In the second locking position 112, the edge 220 is concealed by a light-colored frame 310, as illustrated in FIG. 3B, which makes the one or more orientation elements 212 identifiable again.

The edge 220 has the same color as or a similar color to the orientation elements 212, which in FIG. 3A, as in FIG. 2A, is a black color, although it may also be another dark color. The frame 310 has a color which contrasts with the color of the edge 220, which in FIG. 3B, as in FIG. 2B, is a white color, although it may also be another light color.

The identifying feature 200 may be a one-, two- or multi-dimensional code, for example a data matrix code, DMC, as described above.

The indicator element 120 may be placed on the locking element 110, wherein a movement of the locking element 110 into the second locking position 112 makes the indicator element 120 detectable, in accordance with the illustration in FIG. 3B.

The indicator element 120 may be discernible and be read, for example, by means of a reader, for example a scannable element, when the one or more orientation elements 212 are not made at least partially unidentifiable.

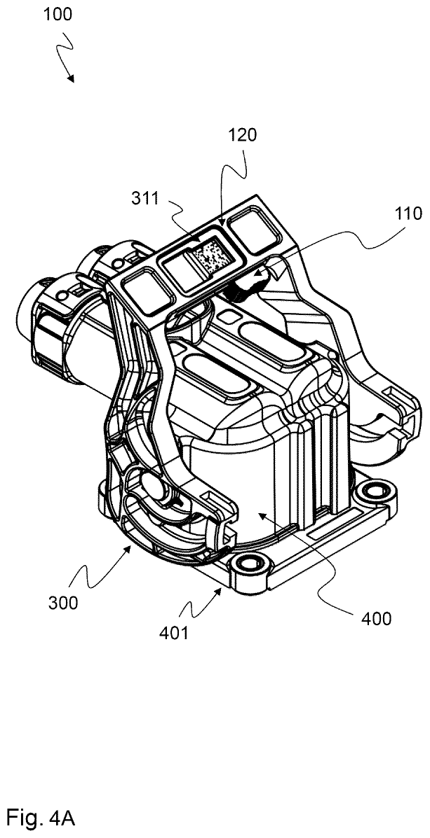

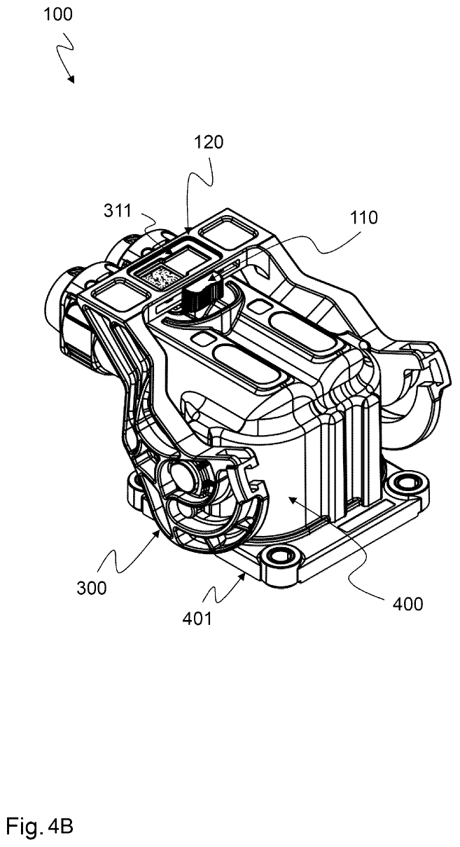

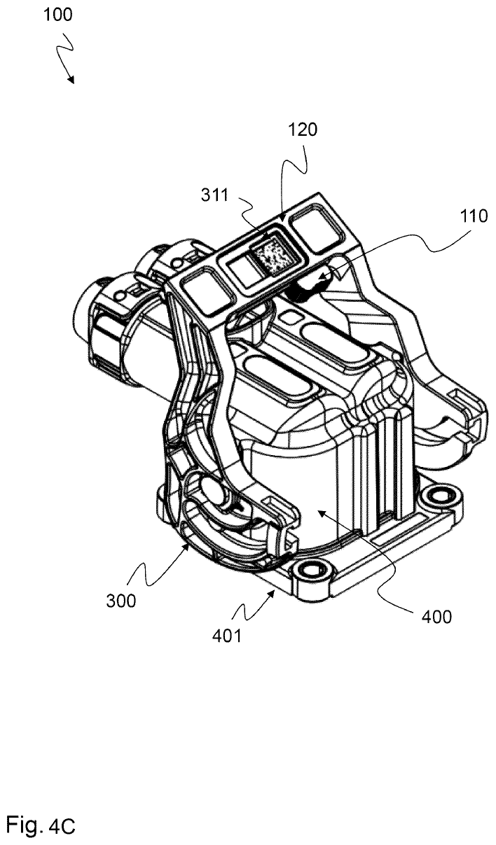

The securing device 100 may be designed to perform connector position assurance (CPA) to secure the locking of a connector housing 400 to a mating connector housing 401, as described in more detail below in relation to FIGS. 4A to 4C.

The securing device 100 and a reader make it possible to implement a securing system which can reliably determine the state of the locking element 110 and transfer this state, for example to a controller, for further processing. Such a securing system includes a securing device 100 as described above and a reader. The reader is designed to detect the indicator element 120 when the locking element 110 is in the second locking position 112, i.e. when the indicator element 120 is detectable, in order to thus detect locking.

The reader may be designed to detect the indicator element 120 only when the locking element 110 is in the second locking position 112 and to detect correct locking only in this second locking position 112.

The reader may forward the detected information, for example the read-out code, to a controller, which then can indicate a fault and take corresponding steps to control the production process.

FIGS. 4A, 4B and 4C show perspective views of a securing device 100 including a locking element 110, an indicator element 120 and a clamping element 300. FIG. 4A illustrates an open securing device 100 according to a first variant or example, in which the clamping element 300 is in an open clamping-clip position. FIG. 4B illustrates the securing device 100 according to the first variant in a closed clamping-clip position. FIG. 4C illustrates an open securing device 100 according to a second variant or example, in which the clamping element 300 is in an open clamping-clip position. The first variant also corresponds to FIGS. 2A and 2B, whereas the second variant corresponds to FIGS. 3A and 3B.

The securing device 100 is designed to perform connector position assurance (CPA) to secure the locking of a connector housing 400 to a mating connector housing 401.

In addition to the locking element 110 and indicator element 120 that are already described above, the securing device 100 also includes a clamping element 300, for example a clamping clip, for clamping the connector housing 400 into the mating connector housing 401.

The clamping element 300 can be moved from an open clamping-element position (see FIGS. 4A and 4C), in which the connector housing 400 can be inserted into the mating connector housing 401, into a closed clamping-element position (see FIG. 4B), in which the connector housing 400 is fastened to the mating connector housing 401 with electrical contact.

The locking element 110 is placed on the clamping element 300 and is designed to lock or to unlock the clamping element 300.

The indicator element 120 indicates an item of information when the locking element 110 is in the second locking position 112, as illustrated in FIG. 4B. Indication of the item of information means that locking of the clamping element 300 by the locking element 110 is present.

In the closed clamping-element position, the locking element 110 can be moved from the first locking position 111 (see FIGS. 4A and 4C) into the second locking position 112 (see FIG. 4B). The locking element 110 is designed, in the second locking position 112, to lock the clamping element 300 in the closed clamping-element position and, in the first locking position 111, to unlock the clamping element 300 for a movement into the open clamping-element position.

The clamping element 300 has a cutout 311, as illustrated in FIGS. 4A to 4C and also in FIG. 3A.

The indicator element 120 is placed on the clamping element 300, for example on a panel or a central bar of the clamping element 300. The locking element 110 is also placed on the clamping element 300.

When the locking element 110 is being moved into the second locking position 112, the indicator element 120 is moved underneath the cutout 311 in the clamping element 300, and therefore makes the one or more orientation elements 212 identifiable, with the result that the indicator element 120 can be detected.

In the first variant according to FIGS. 4A and 4B, the identifying feature 200 is applied to the CPA system with a peripheral black frame. Actuating the CPA system causes it to slide underneath the clamping element 300 or clip. There is a cutout 311 in the clamping element 300 or clip. This cutout 311 is designed such that the orientation elements 212 can be discerned clearly again. The identifying feature 200 is visible and not concealed. It is only represented such that the orientation elements 212 are not discernible in the first locking position, as illustrated in FIG. 3A. In the second locking position 112, the orientation elements 212 of the identifying feature 200 are discernible, as illustrated in FIG. 4B.

In the second variant according to the illustration in FIG. 4C, an additional edge is slid around the orientation elements 212 of the identifying feature 200, in order to make them harder to discern, as shown in FIG. 4C.

FIGS. 4A to 4C thus also show a plug connection having a connector housing 400 and a mating connector housing 401, which are connected to one another and secured by the securing device 100 as described above.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A securing device for securing a locking of a locking element, comprising:
the locking element configured to move from a first locking position into a second locking position, the locking element configured to lock in the second locking position; and
an indicator element configured to indicate an item of information, in the first locking position, the indicator element is visible and is not concealed, the indicator element including one or more orientation elements configured to mark an orientation of the indicator element, the indicator element is detectable via the one or more orientation elements, in the first locking position of the locking element, the one or more orientation elements are configured to be at least partially unidentifiable such that the indicator element is not detectable and in the second locking position of the locking element, the one or more orientation elements are configured to be identifiable such that the indicator element is detectable.

2. The securing device according to claim 1, wherein in the first locking position, the one or more orientation elements are configured to be unidentifiable without concealing the one or more orientation elements.

3. The securing device according to claim 1, wherein the indicator element has an identifying feature with a data area configured to detect the identifying feature, the one or more orientation elements are placed on an edge of the data area and when the one or more orientation elements are at least partially unidentifiable, the identifying feature is no longer detectable.

4. The securing device according to claim 3, wherein the identifying feature includes a quiet area which runs around a periphery of the data area and the one or more orientation elements, and in the first locking position of the locking element, the quiet area is at least partially concealed and the identifying feature is no longer identifiable.

5. The securing device according to claim 3, wherein the indicator element has an edge that runs around a periphery of the identifying feature and makes the one or more orientation elements unidentifiable and in the second locking position, the edge is concealed by a frame that makes the one or more orientation elements identifiable.

6. The securing device according to claim 5, wherein the edge has a similar color to the one or more orientation elements, and the frame has a color which contrasts with the color of the edge.

7. The securing device according to claim 3, wherein the identifying feature includes a code.

8. The securing device according to claim 1, wherein the indicator element is placed on the locking element and a movement of the locking element into the second locking position enables the indicator element to be detectable.

9. The securing device according to claim 1, wherein the indicator element is discernible when the one or more orientation elements are not made at least partially unidentifiable.

10. The securing device according to claim 1, wherein the securing device is configured to perform connector position assurance (CPA) to secure a lock of a connector housing and a mating connector housing.

11. The securing device according to claim 10, further comprising:
a clamping element configured to clamp the connector housing into the mating connector housing, the clamping element configured to move from an open clamping-element position, in which the connector housing is configured to be inserted into the mating connector housing, into a closed clamping-element position, in which the connector housing is fastened to the mating connector housing with electrical contact; and
wherein the locking element is placed on the clamping element and configured to lock or to unlock the clamping element.

12. The securing device according to claim 11, wherein in the closed clamping-element position, the locking element is configured to move from the first locking position into the second locking position and is configured, in the second locking position, to lock the clamping element in the closed clamping-element position and in the first locking position, is configured to unlock the clamping element which is configured to move into the open clamping-element position.

13. The securing device according to claim 12, wherein the clamping element includes a cutout, the indicator element is placed on the clamping element, and when the locking element is being moved into the second locking position, the indicator element is moved underneath the cutout in the clamping element to enable the one or more orientation elements to be identifiable such that the indicator element is detectable.
